(19) United States
(12) Patent Application Publication
(10) Pub. No.: US 2008/0273389 A1
(43) Pub. Date: Nov. 6, 2008

(54) Flash memory cells, NAND cell units, methods of forming NAND cell units, and methods of programming NAND cell unit strings

(75) Inventors: Seiichi Aritome, Boise, ID (US); Di Li, Boise, ID (US)

Correspondence Address: WELLS ST. JOHN P.S., 601 W. FIRST AVENUE, SUITE 1300, SPOKANE, WA, 99201, US

(73) Assignee: Micron Technology, Inc.

(21) Appl. No.: 11/726,320

(22) Filed: Mar. 21, 2007

(51) Int. Cl. G11C 16/04

(52) U.S. Cl. 365/185.17

(57) ABSTRACT

Some embodiments include utilization of alternating first and second gate types along NAND strings, with the second gate types having floating gates thicker than floating gates of the first gate types, and capacitively coupled with control gates of the first gate types. The second gate types may be multilevel cell (MLC) devices, and pass voltage applied to the control gates of the first gate types may be utilized to reduce programming voltages utilized to reach memory states of the MLC devices. Some embodiments include NAND cell units, and some embodiments include methods of forming NAND cell units. Also, some embodiments include methods of programming NAND cell unit string gates in which programming voltage applied to a first string gate is held below a threshold, and pass voltage applied to an adjacent string gate is increased and utilized to program the first string gate.

### TECHNICAL FIELD

Flash memory cells, NAND cell units, methods of forming NAND cell units, and methods of programming NAND cell unit strings.

### BACKGROUND

Memory devices provide data storage for electronic systems. One type of memory is a non-volatile memory known as flash memory. A flash memory is a type of EEPROM (electrically-erasable programmable read-only memory) that may be erased and reprogrammed in blocks. Many modern personal computers have BIOS stored on a flash memory chip. Such a BIOS is sometimes called a flash BIOS. Flash memory is also popular in wireless electronic devices because it enables the manufacturer to support new communication protocols as they become standardized, and to provide the ability to remotely upgrade the device for enhanced features.

A typical flash memory comprises a memory array that includes a large number of memory cells arranged in row and column fashion. The cells are usually grouped into blocks. Each of the cells within a block may be electrically programmed by charging a floating gate. The charge may be removed from the floating gate by a block erase operation. Data is stored in a cell as charge in the floating gate.

NAND is a basic architecture of flash memory. A NAND cell unit comprises at least one select gate coupled in series to a serial combination of memory cells (with the serial combination being commonly referred to as a NAND string). The gates of the NAND string have traditionally been single level cells (SLCs), but manufacturers are transitioning to utilization of multilevel cells (MLCs) for gates of NAND strings. An SLC stores only one data bit, whereas an MLC stores multiple data bits. Accordingly, memory can be at least doubled by transitioning from SLCs to MLCs.

MLCs differ from SLCs in the programming of the devices. Specifically, a device may be programmed as an SLC if the device is programmed to have only two memory states (0 or 1), with one of the memory states corresponding to one level of stored charge at a floating gate (for example, corresponding to the fully charged device) and the other corresponding to another level of stored charge at the floating gate (for example, corresponding to the fully discharged device). Alternatively, the device may be programmed as an MLC having two bits of memory if the device is programmed to have four memory states. The memory states may be designated as the 11, 01, 00, and 10 memory states, in order from lowest stored charge (for example, fully discharged) to highest stored charge (for example, fully charged). Accordingly, the 11 state corresponds to a lowest stored charge state, the 10 state corresponds to a highest stored charge state, and the 01 and 00 states correspond to first and second intermediate levels of stored charge.

In order to have four distinct programmable states, an MLC may need a greater programming voltage to reach the highest charged memory state than is needed by an SLC. This can lead to complications in transitioning to MLCs in that the high programming voltages utilized for MLC device programming may exceed the safe high voltage (SHV) of an integrated circuit assembly, and may lead to damaged wiring, and/or to damaged integrated circuit devices.

### BRIEF DESCRIPTION OF THE DRAWINGS

FIG. 1 is a simplified block diagram of a memory system in accordance with an embodiment.

FIG. 2 is a schematic of a NAND memory array in accordance with an embodiment.

FIG. 3 is a diagrammatic cross-sectional view of portions of a semiconductor wafer illustrating an embodiment of a NAND cell unit.

FIG. 4 is a graphical illustration of the change in programming voltage, pass voltage, and floating gate charge over time in accordance with an embodiment.

FIG. 5 is a graphical illustration of the change in programming voltage (V_{pgm}) and pass voltage (Vₚₐₛₛ) in accordance with an embodiment.

FIG. 6 is a graphical illustration of the change in programming voltage (V_{pgm}) and pass voltage (Vₚₐₛₛ) in accordance with an embodiment.

FIG. 7 is a three-dimensional view of a portion of a semiconductor wafer illustrating an embodiment of a NAND cell unit.

FIGS. 8-10 illustrate portions of a semiconductor wafer at various processing stages of an embodiment.

FIG. 11 is a diagrammatic view of a computer embodiment.

FIG. 12 is a block diagram showing particular features of the motherboard of the FIG. 11 computer embodiment.

FIG. 13 is a high level block diagram of an electronic system embodiment.

FIG. 14 is a simplified block diagram of a memory device embodiment.

### DETAILED DESCRIPTION OF THE PREFERRED EMBODIMENTS

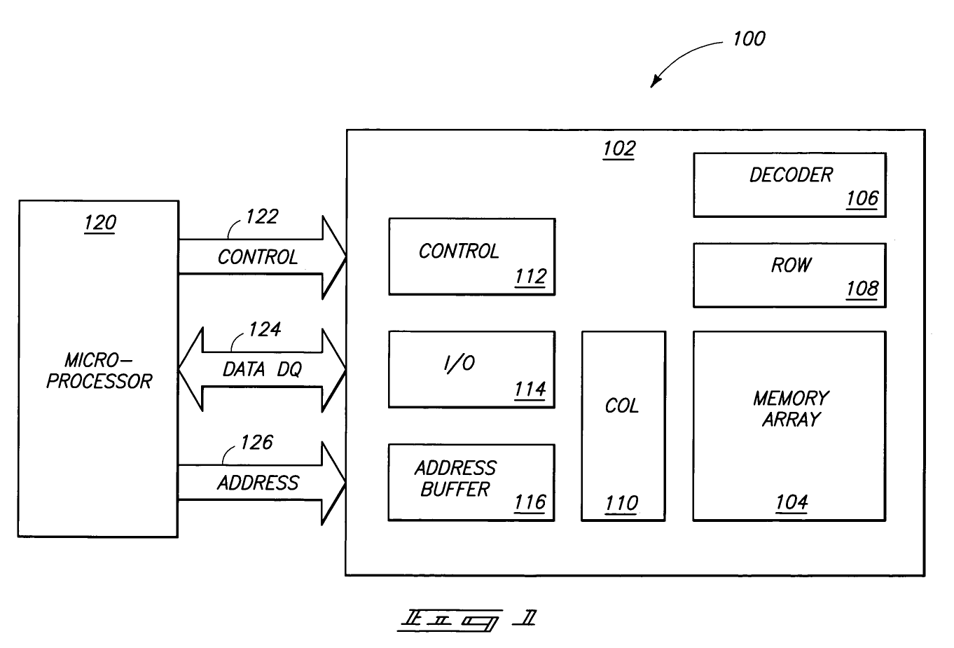

FIG. 1 is a simplified block diagram of a memory system 100, according to an embodiment. Memory system 100 includes an integrated circuit flash memory device 102 (e.g., a NAND memory device), that includes an array of floating-gate memory cells 104, an address decoder 106, row access circuitry 108, column access circuitry 110, control circuitry 112, input/output (I/O) circuitry 114, and an address buffer 116. Memory system 100 includes an external microprocessor 120, or memory controller, electrically connected to memory device 102 for memory accessing as part of an electronic system. The memory device 102 receives control signals from the processor 120 over a control link 122. The memory cells are used to store data that is accessed via a data (DQ) link 124. Address signals are received via an address link 126, and are decoded at address decoder 106 to access the memory array 104. Address buffer circuit 116 latches the address signals. The memory cells may be accessed in response to the control signals and the address signals.

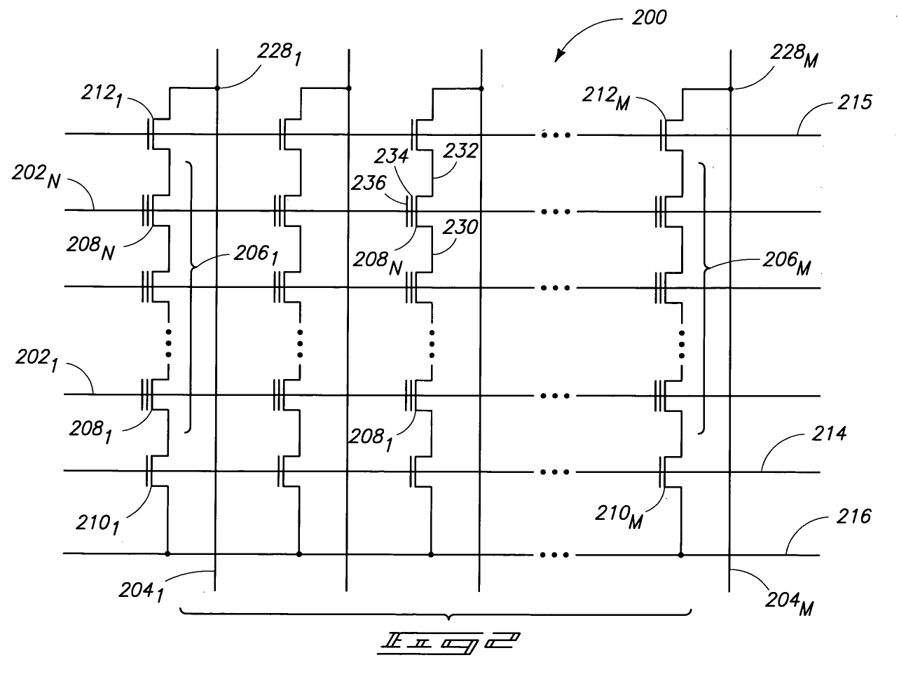

FIG. 2 is a schematic of a NAND memory array 200. Such may be a portion of memory array 104 of FIG. 1. Memory array 200 includes wordlines 202₁ to 202_{N}, and intersecting local bitlines 204₁ to 204_{M}. The number of wordlines 202 and the number of bitlines 204 may be each some power of two, for example, 256 wordlines and 4,096 bitlines. The local bitlines 204 may be coupled to global bitlines (not shown) in a many-to-one relationship.

Memory array 200 includes NAND strings 206₁ to 206_{M}. Each NAND string includes floating gate transistors 208₁ to 208_{N}. The floating gate transistors are located at intersections of wordlines 202 and a local bitlines 204. The floating gate transistors 208 represent non-volatile memory cells for storage of data. The floating gate transistors 208 of each NAND string 206 are connected in series source to drain between a source select gate 210 and a drain select gate 212. Each source select gate 210 is located at an intersection of a local bitline 204 and a source select line 214, while each drain select gate 212 is located at an intersection of a local bitline 204 and a drain select line 215.

A source of each source select gate 210 is connected to a common source line 216. The drain of each source select gate 210 is connected to the source of the first floating-gate transistor 208 of the corresponding NAND string 206. For example, the drain of source select gate 210₁ is connected to the source of floating-gate transistor 208₁ of the corresponding NAND string 206₁. The source select gates 210 are connected to source-select line 214.

The drain of each drain select gate 212 is connected to a local bitline 204 for the corresponding NAND string at a drain contact 228. For example, the drain of drain select gate 212₁ is connected to the local bitline 204₁ for the corresponding NAND string 206₁ at drain contact 228₁. The source of each drain select gate 212 is connected to the drain of the last floating-gate transistor 208 of the corresponding NAND string 206. For example, the source of drain select gate 212₁ is connected to the drain of floating gate transistor 208_{N} of the corresponding NAND string 206₁.

Floating gate transistors 208 include a source 230 and a drain 232, a floating gate 234, and a control gate 236. Floating gate transistors 208 have their control gates 236 coupled to a wordline 202. A column of the floating gate transistors 208 are those NAND strings 206 coupled to a given local bitline 204. A row of the floating gate transistors 208 are those transistors commonly coupled to a given wordline 202.

As discussed above in the “Background” section, programming of MLC devices can be difficult due to the high voltages utilized to program higher memory states of the devices. The memory states most difficult to program are the those having the greatest charge on the floating gate (for instance, the memory states referred to above as the 00 and 10 memory states). Some embodiments described herein may be utilized to reduce the programming voltage utilized to program memory states of an MLC device. The embodiments may be utilized during programming of any of the memory states of the MLC device, but may be particularly useful during programming of states that would otherwise require high voltage.

Some embodiments include utilization of alternating first and second gate types along NAND strings, with the second gate types having floating gates capacitively coupled with control gates of the first gate types. The second gate types may be MLC devices, and pass voltage applied to the control gates of the first gate types may be utilized to reduce a programming voltage utilized to reach fully charged memory states of the MLC devices.

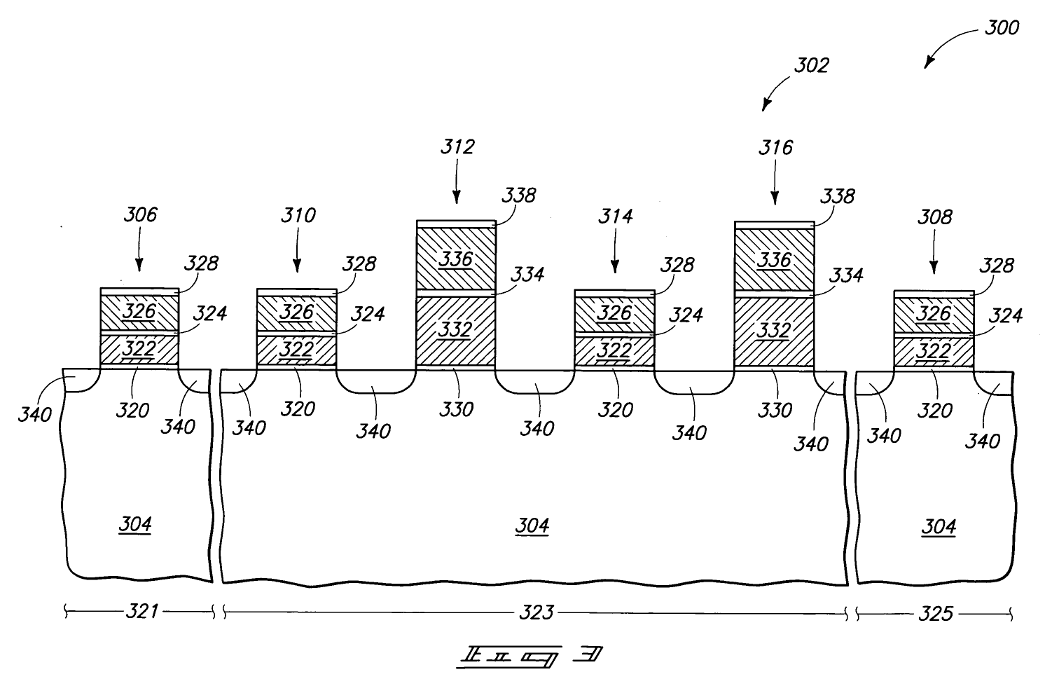

An example embodiment is shown in FIG. 3. Specifically, FIG. 3 shows portions of a semiconductor wafer assembly 300 comprising a NAND cell unit 302.

The semiconductor wafer assembly comprises a base 304. Such base may comprise, consist essentially of, or consist of monocrystalline silicon, and may be considered to be a semiconductor substrate, or at least a portion of a semiconductor substrate. To aid in interpretation of the claims that follow, the terms “semiconductive substrate,” “semiconductor construction” and “semiconductor substrate” mean any construction comprising semiconductive material, including, but not limited to, bulk semiconductive materials such as a semiconductive wafer (either alone or in assemblies comprising other materials), and semiconductive material layers (either alone or in assemblies comprising other materials). The term “substrate” refers to any supporting structure, including, but not limited to, the semiconductive substrates described above.

Base 304 is shown to be homogenous, but may comprise numerous layers in some embodiments. For instance, base 304 may correspond to a semiconductor substrate containing one or more layers associated with integrated circuit fabrication. The layers may, for example, correspond to one or more of metal interconnect layers, barrier layers, diffusion layers, insulator layers, etc.

The NAND cell unit comprises a pair of select gates 306 and 308, and comprises a plurality of string gates 310, 312, 314 and 316 between the select gates. Adjacent string gates, such as gates 310 and 312, may be spaced from one another by a distance of less than or equal to about 50 nanometers, such as, for example, a distance of from about 20 nanometers to about 30 nanometers.

Assembly 300 is shown subdivided into three portions 321, 323 and 325 to illustrate that there may be more than the shown four string gates between the two select gates. In other embodiments there may be less than the shown four string gates.

String gates 310 and 314 are similar to one another and comprise gate dielectric 320, floating gates 322, intergate dielectric material 324, control gates 326 and electrically insulative caps 328. The gate dielectric may comprise any suitable electrically insulative composition, or combination of compositions, and may, for example, comprise, consist essentially of, or consist of silicon dioxide. The floating gates may comprise any suitable composition or combination of compositions for charge storage, and may, for example, comprise, consist essentially of, or consist of semiconductor materials (for instance, silicon), and/or charge trapping materials (for instance, silicon nitride and silicon oxynitride). The intergate dielectric material may comprise any suitable composition or combination of compositions, and may, for example, comprise a layer of silicon nitride sandwiched between a pair of silicon dioxide layers (so-called ONO). The control gates may comprise any suitable composition or combination of compositions, and may, for example, comprise, consist essentially of, or consist of one or more of various metals (for instance, titanium or tungsten), metal-containing compounds (for instance, metal silicides or metal nitrides), or conductively-doped semiconductor materials (for instance, conductively-doped silicon). The electrically insulative caps may comprise any suitable composition or combination of compositions, and many for example, comprise, consist essentially of, or consist of one or more of silicon dioxide, silicon nitride and silicon oxynitride.

String gates 312 and 316 are similar to one another and comprise gate dielectric 330, floating gates 332, intergate dielectric material 334, control gates 336 and electrically insulative caps 338. The gate dielectric may comprise any suitable electrically insulative composition, or combination of compositions, and may, for example, comprise, consist essentially of, or consist of silicon dioxide. The floating gates may comprise any suitable composition or combination of compositions for charge storage, and may, for example, comprise, consist essentially of, or consist of semiconductor materials (for instance, silicon). The intergate dielectric material may comprise any suitable composition or combination of compositions, and may, for example, comprise a layer of silicon nitride sandwiched between a pair of silicon dioxide layers (so-called ONO). The control gates may comprise any suitable composition or combination of compositions, and may, for example, comprise, consist essentially of, or consist of one or more of various metals (for instance, titanium or tungsten), metal-containing compounds (for instance, metal silicides or metal nitrides), or conductively-doped semiconductor materials (for instance, conductively-doped silicon). The electrically insulative caps may comprise any suitable composition or combination of compositions, and may for example, comprise, consist essentially of, or consist of one or more of silicon dioxide, silicon nitride and silicon oxynitride.

Source/drain regions 340 are provided within base 304 adjacent the select gates 306 and 308, and adjacent the string gates 310, 312, 314 and 316. The source/drain regions may correspond to conductively-doped regions of semiconductor material of base 304, and may be either n-type doped or p-type doped.

String gates 310 and 314 may be considered to be representative of a first string gate type (or first flash memory cell type) having a first floating gate thickness, and string gates 312 and 316 may be considered to be representative of a second string gate type (or second flash memory cell type) having a second floating gate thickness which is greater than the first floating gate thickness. The second thickness may be at least about four-times greater than the first thickness in some embodiments. For instance, the first thickness may be about 20 nanometers, and the second thickness may be about 80 nanometers. The first and second string gate types alternate with one another between the select gates 306 and 308. In some embodiments, a string gate of the second type (for instance, string gate 312) may be considered to be interjacent a pair of string gates of the first type (for instance, string gates 310 and 314). In some embodiments, the first type string gates 310 and 314 may be referred to as first string gates, while the second type string gates 312 and 316 are referred to as a second string gates.

The floating gates 322 and control gates 326 of the first string gates 310 and 314 may be considered to be first floating gates and first control gates, while the floating gates 332 and control gates 336 of the second string gates 312 and 316 are considered to be second floating gates and second control gates. In the shown embodiment, portions of the first control gates 326 are at the same height above an upper surface of base 304 as portions of the second floating gates 332. The portions which are at the same height as one another may be considered to be at a “common elevation” with one another.

The common elevation of portions of the first control gates 326 with portions of the second floating gates 332 enhances capacitive coupling between the first control gates and the second floating gates. The enhanced capacitive coupling can be utilized to enable voltage applied to the first control gates 326 to influence the programming voltage of the second string gates 312 and 316. Such influence may allow reduction of the programming voltage of the second string gates, as discussed below.

The second string gates 312 and 316 may correspond to MLC devices, and accordingly may have one or more memory states programmed with relatively high voltage. The first string gates 310 and 314 may correspond to SLC devices, with an advantage in using SLC devices being that such devices sometimes have thinner floating gates than MLC devices. If the first string gates are SLC devices and the second string gates are MLC devices, the NAND string of FIG. 3 will not have as much memory density as it would if all of the string gates were MLC devices. However, an advantage of including the SLC devices is that they may be utilized to assist in programming the MLC devices through the capacitive coupling of the first control gates 326 with the second floating gates 332.

The first and second floating gates 322 and 332 may comprise the same composition as one another, or may be different in composition from one another; and similarly the first and second control gates 326 and 336 may comprise the same composition as one another, or may be different in composition from one another. It can be advantageous for the second floating gates 332 to comprise material within which charge is mobile, such as semiconductor material (for instance, silicon) so that capacitive coupling with adjacent first control gates causes changes that permeate throughout the second floating gates. Accordingly, the second floating gates may consist essentially of, or consist of silicon in some embodiments. The first floating gates 322 may comprise material within which charge is mobile, or may comprise charge trapping materials (for instance, silicon nitride or silicon oxynitride).

The select gates 306 and 308 are shown to be similar to first string gates 310 and 314. Such can occur if select gates 306 and 308 are patterned at the same time as string gates 310 and 314, and from the same materials. In other embodiments, the select gates may be similar to the second string gates 312 and 316. In yet other embodiments, the select gates may be field effect transistors which are not similar to any of the string gates.

The string gates of FIG. 3 may be considered to be a plurality of flash memory cells coupled in series. The cross-sectional view of FIG. 3 shows that floating gates of adjacent memory cells have different cross-section thickness along the common vertical plane of the cross-sectional view.

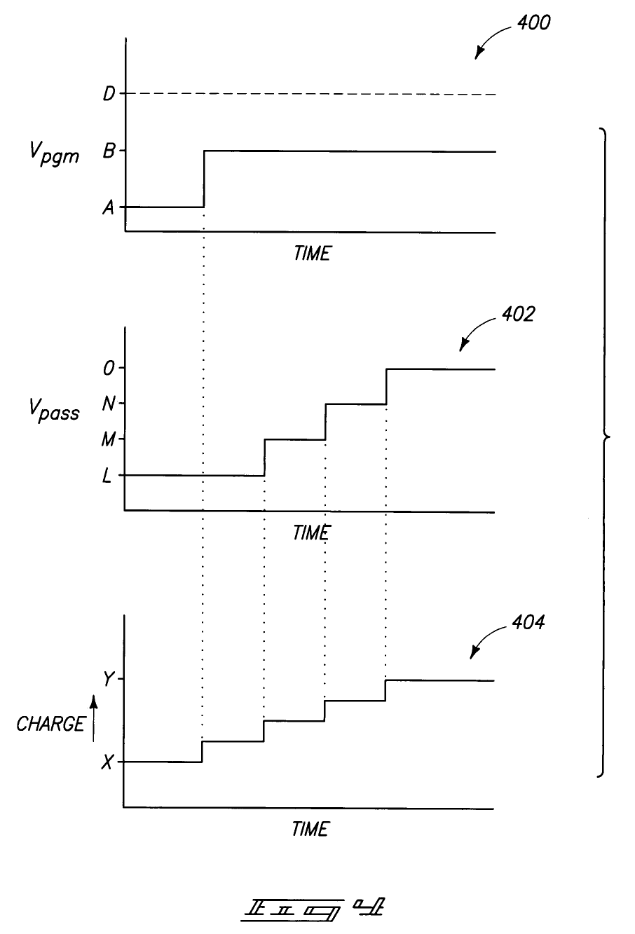

FIG. 4 illustrates a procedure for utilizing cross coupling between a first control gate 326 (FIG. 3) and a second floating gate 332 (FIG. 3) during programming of an MLC comprising the second floating gate. Specifically, FIG. 4 shows a top graph 400 illustrating the manipulation of programming voltage (V_{pgm}) over time during programming of one of the second string gates (for instance, 312 of FIG. 3). FIG. 4 also shows a middle graph 402 illustrating the manipulation of a pass voltage (Vₚₐₛₛ) through the control gate of one or both of the first string gates (310 and 314 of FIG. 3) adjacent the second string gate. Additionally, FIG. 4 shows a bottom graph 404 illustrating the change in floating gate charge occurring during the programming of the second string gate.

The floating gate charge goes from a first level “X” to a second level “Y” during the programming, which corresponds to a change from one memory state to another. Such change may be a change to any of the charged states of the MLC device, and may, for example, be a change to the highest partially charged state (in other words, the state designated as 00 above), or maybe a change to the fully charged state (in other words, the state designated as 10 above).

The cross coupling between the floating gate of the second string gate (312 of FIG. 3) and control gates of one or both of the adjacent first string gates (310 and 314 of FIG. 3) allows the pass voltage to be utilized to reduce the programming voltage. The graph 400 has a dashed line at level “D”. The level “D” corresponds to a threshold where programming of the MLC to the memory state of level “Y” (graph 404) would occur in the absence of coupling to the pass voltage. Graph 400 also shows transition of the programming voltage from a first level “A” to a second level “B”, which is below the threshold level “D”. The term “programming voltage” refers to a voltage applied directly to the control gate 336 (FIG. 3) of the NAND string gate 312 (FIG. 3). The programming voltage induces a voltage differential between such control gate and the source/drain regions 340 (FIG. 3) adjacent the NAND string gate. In some embodiments, the manipulation of the programming voltage of graph 400 may be considered to be representative of manipulation of the voltage differential between the control gate and the source/drain regions of a NAND string gate during programming of the gate.

The graph 402 shows the pass voltage being incrementally raised from a level “L” to levels “M”, “N” and “O”. Each time the pass voltage is raised to a new level, a verification of the floating gate charge may be conducted to determine if the second string gate has transitioned from the memory state corresponding to level “X” to that corresponding to level “Y”. The incremental increase of the pass voltage and utilization of verification may allow careful control of the programming of the second string gate. Such may avoid utilization of excessive voltage which could otherwise damage adjacent components, or could cause the desired memory state to be overshot if the desired memory state were anything other than the fully charged memory state.

The capacitive coupling of the first control gates with the second floating gate has allowed the charge on the second floating gate to be transitioned from “X” to “Y” while keeping the programming voltage below level “D”. In some embodiments, level “D” may be above the SHV of integrated circuitry comprising the NAND cell unit, and “B” may be below the SHV. The programming voltage may be held at a constant level during programming (such as shown in graph 400 by the constant level “B” during the programming), or may be held at a substantially constant level. The term “substantially constant” is used to indicate that the programming voltage is held constant within limitations of tolerances associated with the programming voltage. In some embodiments, the programming voltage may be varied during the programming. For instance, the programming voltage may be incrementally increased in addition to, or alternatively to, the incremental increase of the pass voltage.

In some embodiments, the NAND string gate 310 of FIG. 3 may be considered a first NAND string gate having a first control gate, and the NAND the string gate 312 of FIG. 3 may be considered a second NAND string gate having a second control gate. The programming of FIG. 4 may be considered to comprise application of a first voltage (Vₚₐₛₛ) to the first control gate, application of a second voltage (V_{pgm}) to the second control gate, and then increasing of the first voltage to program the second NAND string gate to a memory state. In some embodiments, the pass voltage may be at least about 9 volts, the threshold level “D” of graph 400 may be about 20 volts, and the level “B” of graph 400 may be less than or equal to about 18 volts. Thus, in some embodiments the utilization of the capacitive coupling of adjacent control gates to a programmed floating gate can reduce a programming voltage by at least about 2 volts.

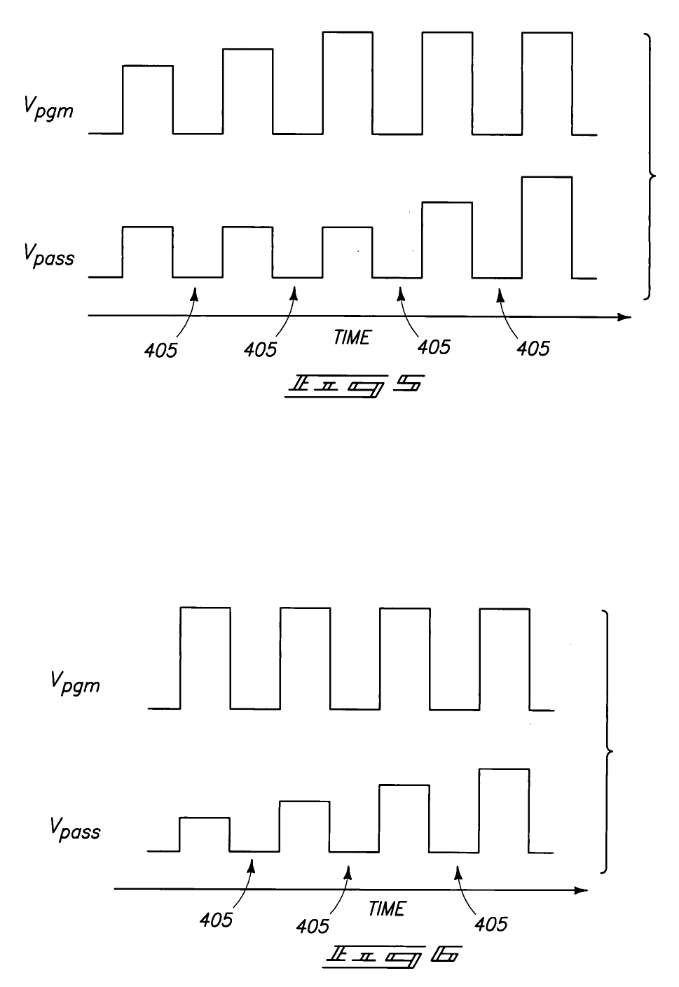

FIGS. 5 and 6 illustrate a couple of embodiments for varying programming voltage (V_{pgm}) on a particular NAND string gate and/or varying pass voltage (Vₚₐₛₛ) on one or more string gates immediately adjacent the particular NAND string gate during programming of the particular NAND string gate.

FIG. 5 shows the programming voltage incrementally increased to a maximum, and thereafter the pass voltage incrementally increased to complete the programming. The maximum of the programming voltage may be limited by a breakdown voltage.

FIG. 6 shows the programming voltage maintained at a constant level, and the pass voltage incrementally increased during the programming.

Verification operations may be conducted between each of the incremental steps of the processes of FIGS. 5 and 6. Such verifications operations may occur at, for example, the locations designated as 405. It is noted that the programming voltage of FIG. 6 fluctuates during the verification steps (specifically, is reduced), but remains substantially constant during the programming (which occurs between the verification steps).

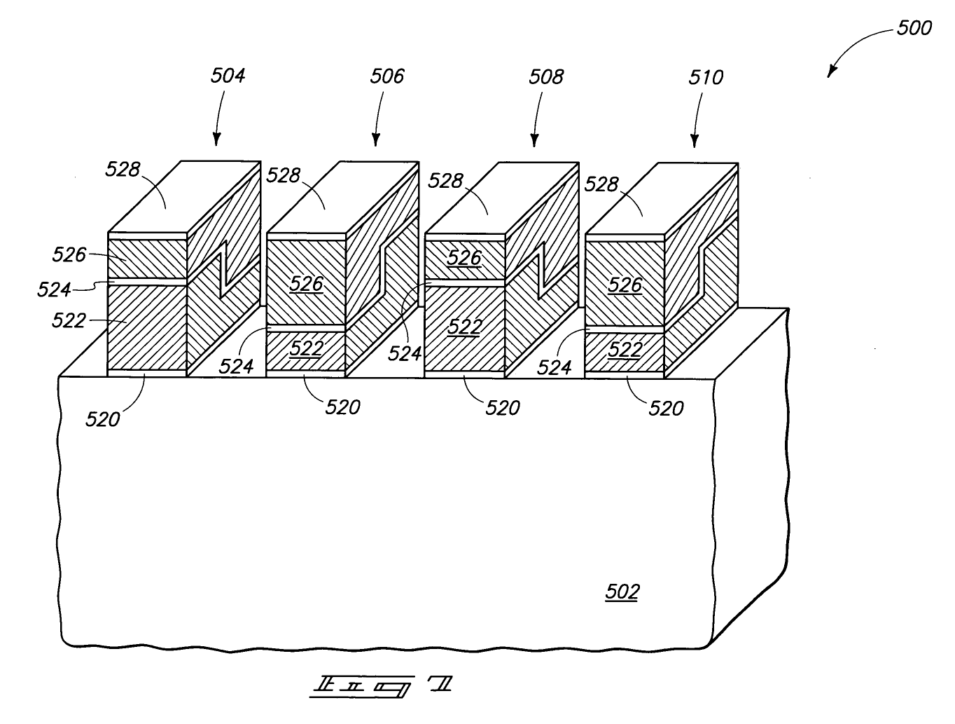

The construction of FIG. 3 is an example construction in which a control gate of one NAND string gate has a portion at a common elevation with a portion of a floating gate of an adjacent NAND string gate. Another example construction having a control gate with a portion at a common elevation with a portion of an adjacent floating gate is illustrated in FIG. 7 as a semiconductor construction 500. The construction of FIG. 7 comprises a base 502, and a plurality of NAND string gates 504, 506, 508 and 510 over the base. The NAND string gates may be between a pair of NAND select gates (not shown).

The base 502 may be identical to the base 304 discussed above with reference to FIG. 3.

The NAND string gates comprise gate dielectric 520, floating gate material 522, intergate dielectric 524, control gate material 526 and electrically insulative capping material 528. The NAND string gates are identical to one another, but alternate between orientations. Specifically, NAND string gates 504 and 508 are in a first orientation, and NAND string gates 506 and 510 are in a second orientation rotated 180 degrees relative to the first orientation. The programming of FIG. 4, 5 or 6 may be utilized to program the individual NAND string gates of FIG. 7.

The embodiments of FIGS. 3 and 7 illustrate examples in which a plurality of flash memory cells are coupled in series, with floating gates of adjacent memory cells having different cross-section thickness along a common vertical plane. In the embodiment of FIG. 3 one of the adjacent floating gates is thin and the other thick, and the relationship of thin to thick remains throughout an entirety of the floating gates. In contrast, in FIG. 7 the relation of thin to thick alternates in various vertical planes. For example, a first common vertical plane of FIG. 7 may be considered the plane along the front of the three-dimensional fragment shown in FIG. 7, where floating gate 522 of memory cell 504 appears thick and floating gate 522 of adjacent memory cell 506 appears thin. The adjacent floating gates are “L” shaped, and the relationship of thin to thick reverses along another common vertical plane laterally offset from the first vertical plane (for instance, a vertical plane along a back of the shown view of FIG. 7). The adjacent “L-shaped” floating gates of FIG. 7 (for instance the gates of adjacent memory cells 504 and 506) are substantially identical to one another, but asymmetrical relative to a vertical plane; and the adjacent memory cells are flipped relative to one another along the vertical plane. Alternatively, the adjacent floating gates may be considered to be rotated 180° relative to one another along vertically-extending axes of rotation.

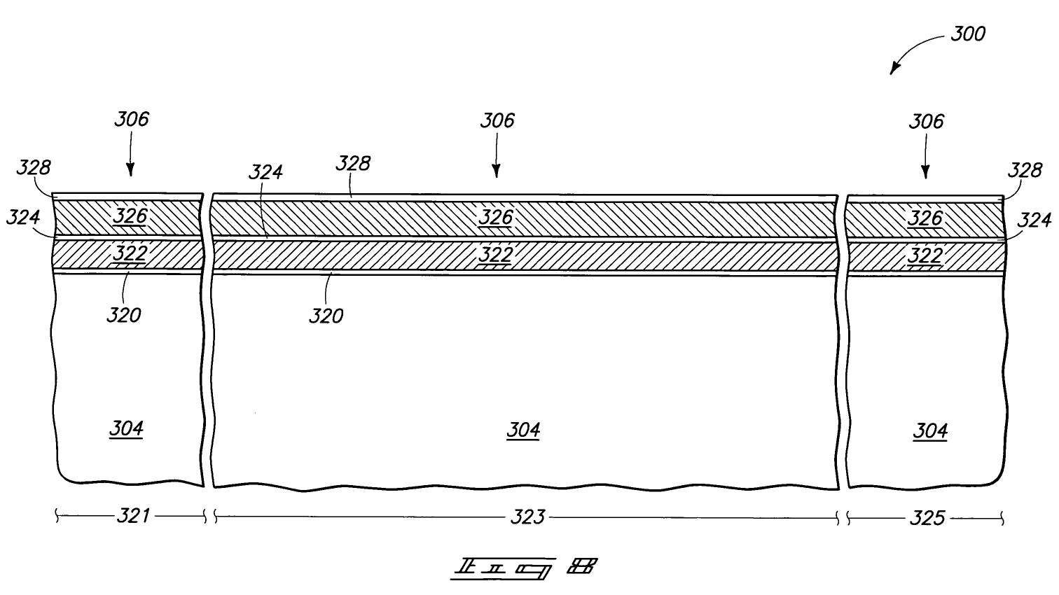

The constructions shown in this disclosure may be formed by any suitable methods. For instance, FIGS. 8-10 illustrate a method for forming the construction of FIG. 3.

FIG. 8 shows construction 300 at an in-process step at which layers of materials 320, 322, 324, 326 and 328 have been formed across portions 321, 323 and 325.

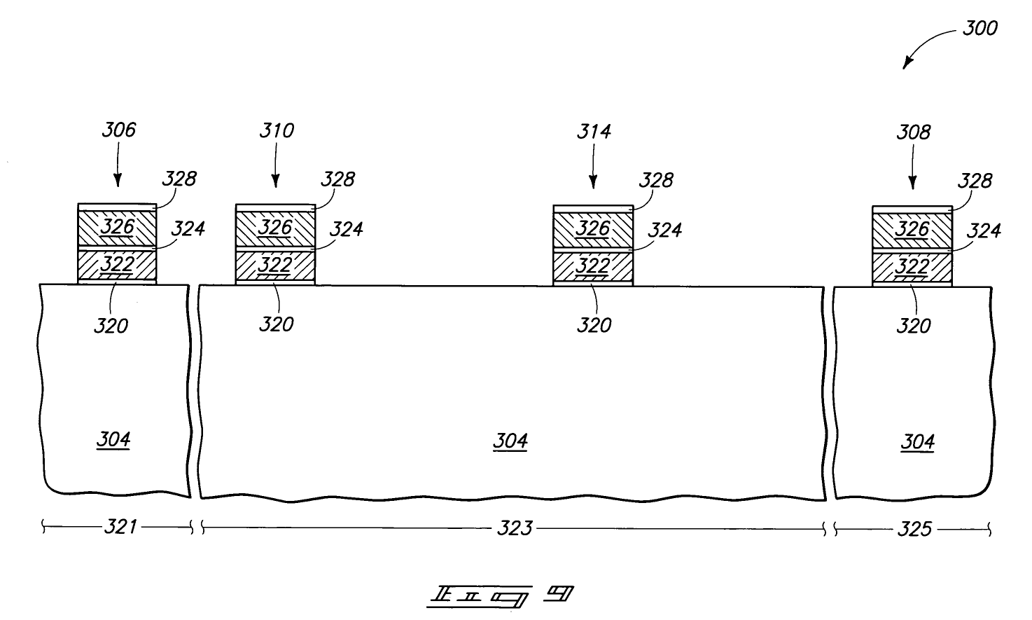

FIG. 9 shows the materials 320, 322, 324, 326 and 328 patterned into select gates 306 and 308, and NAND string gates 310 and 314. Such patterning may be accomplished by providing one or more patterned layers over materials 320, 322, 324, 326 and 328; transferring a pattern from the layers to the materials 320, 322, 324, 326 and 328 with one or more suitable etches; and then removing the patterned layers. One of the patterned layers may correspond to photolithographically patterned photoresist.

FIG. 10 shows a NAND string gates 312 and 316 formed adjacent gates 310 and 314. The NAND string gates 312 and 316 and may be formed by providing layers of materials 330, 332, 334, 336 and 338 over base 304, and then patterning such materials with processing similar to that discussed above for patterning materials 320, 322, 324, 326 and 328 of gates 310 and 314.

Although the embodiment of FIGS. 8-10 shows the NAND string gates having the thinner floating gates being formed before the NAND string gates having the thicker floating gates, in other embodiments the order of formation may be reversed so that the NAND string gates having the thicker floating gates are formed before those having the thinner floating gates.

The select gates 306 and 308 are patterned with NAND string gates 310 and 314 in the embodiment of FIGS. 8-10. In other embodiments, the select gates may be patterned with NAND string gates 312 and 316 so that the select gates are structures comparable to those of gates 312 and 316. In yet other embodiments, the select gates could be patterned separately from all of the string gates.

The NAND cell units discussed above may be utilized in electronic systems, such as, for example, computer systems.

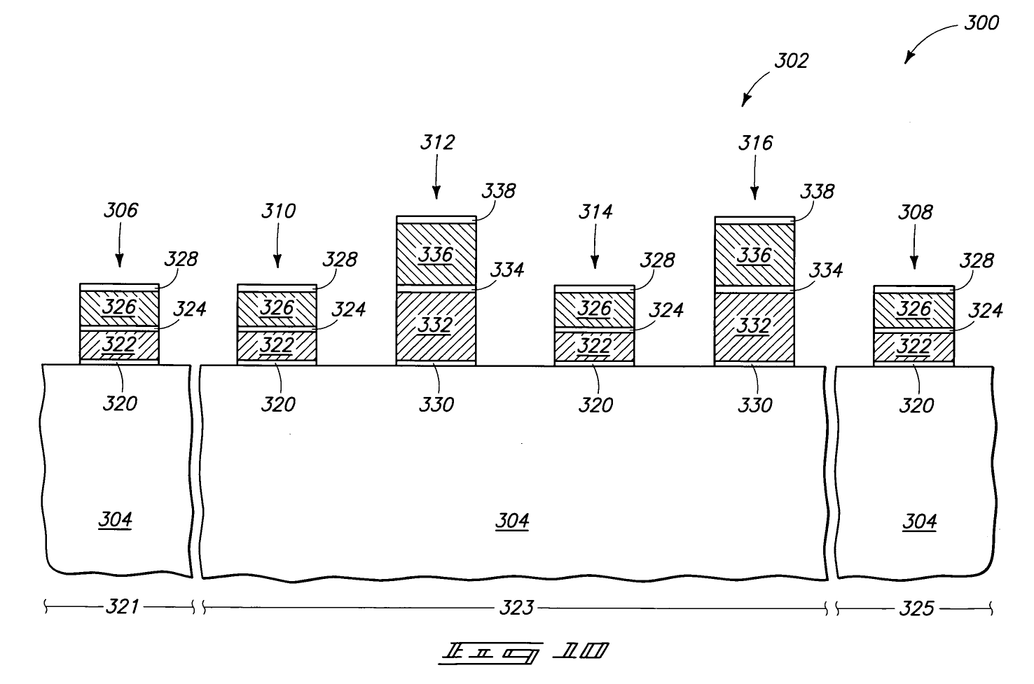

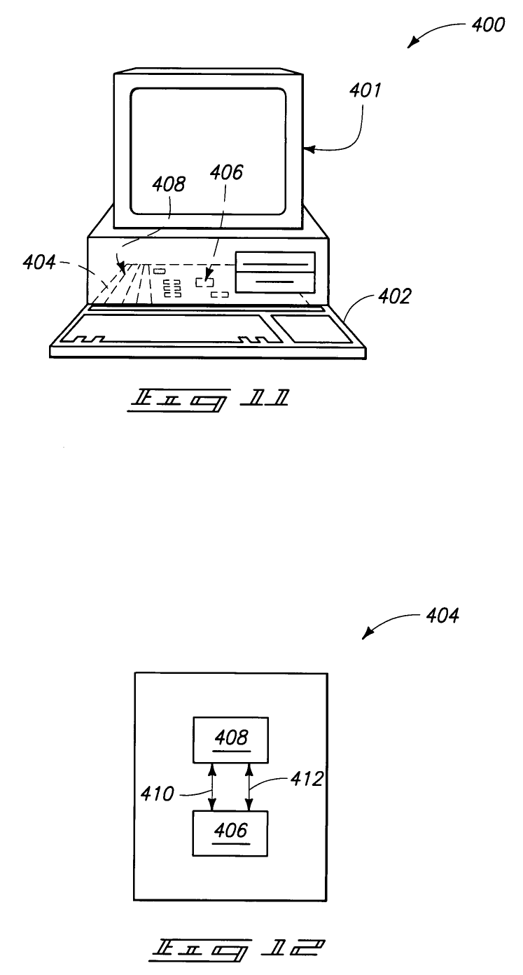

FIG. 11 illustrates an embodiment of a computer system 400. Computer system 400 includes a monitor 401 or other communication output device, a keyboard 402 or other communication input device, and a motherboard 404. Motherboard 404 may carry a microprocessor 406 or other data processing unit, and at least one memory device 408. Memory device 408 may comprise an array of memory cells, and such array may be coupled with addressing circuitry for accessing individual memory cells in the array. Further, the memory cell array may be coupled to a read circuit for reading data from the memory cells. The addressing and read circuitry may be utilized for conveying information between memory device 408 and processor 406. Such is illustrated in the block diagram of the motherboard 404 shown in FIG. 12. In such block diagram, the addressing circuitry is illustrated as 410 and the read circuitry is illustrated as 412.

Processor device 406 may correspond to a processor module, and associated memory utilized with the module may comprise flash structures.

Memory device 408 may correspond to a memory module, and may comprise flash memory.

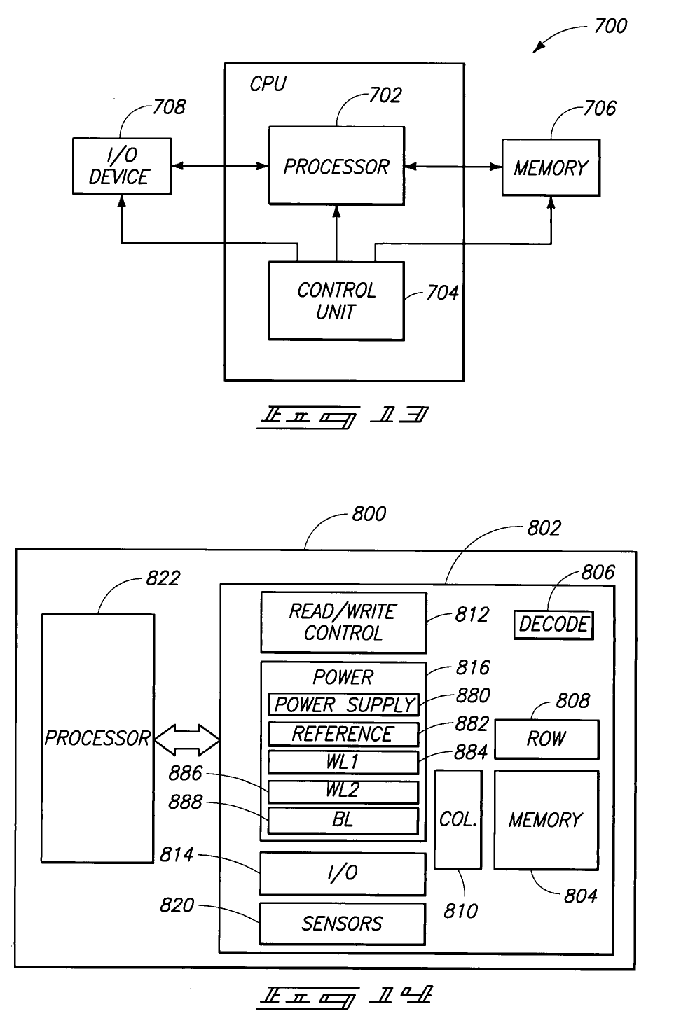

FIG. 13 illustrates a simplified block diagram of a high-level organization of an electronic system 700. System 700 may correspond to, for example, a computer system, a process control system, or any other system that employs a processor and associated memory. Electronic system 700 has functional elements, including a processor 702, a control unit 704, a memory device unit 706 and an input/output (I/O) device 708 (it is to be understood that the system may have a plurality of processors, control units, memory device units and/or I/O devices in various embodiments). Generally, electronic system 700 will have a native set of instructions that specify operations to be performed on data by the processor 702 and other interactions between the processor 702, the memory device unit 706 and the I/O device 708. The control unit 704 coordinates all operations of the processor 702, the memory device 706 and the I/O device 708 by continuously cycling through a set of operations that cause instructions to be fetched from the memory device 706 and executed. The memory device 706 may include flash memory, such as a flash card.

FIG. 14 is a simplified block diagram of an electronic system 800. The system 800 includes a memory device 802 that has an array of memory cells 804, address decoder 806, row access circuitry 808, column access circuitry 810, read/write control circuitry 812 for controlling operations, and input/output circuitry 814. The memory device 802 further includes power circuitry 816, and sensors 820, such as current sensors for determining whether a memory cell is in a low-threshold conducting state or in a high-threshold non-conducting state. The illustrated power circuitry 816 includes power supply circuitry 880, circuitry 882 for providing a reference voltage, circuitry 884 for providing a first wordline with pulses, circuitry 886 for providing a second wordline with pulses, and circuitry 888 for providing a bitline with pulses. The system 800 also includes a processor 822, or memory controller for memory accessing.

The memory device 802 receives control signals from the processor 822 over wiring or metallization lines. The memory device 802 is used to store data which is accessed via I/O lines. At least one of the processor 822 or memory device 802 may include flash memory.

The various electronic systems may be fabricated in single-package processing units, or even on a single semiconductor chip, in order to reduce the communication time between the processor and the memory device(s).

The electronic systems may be used in memory modules, device drivers, power modules, communication modems, processor modules, and application-specific modules, and may include multilayer, multichip modules.

The electronic systems may be any of a broad range of systems, such as clocks, televisions, cell phones, personal computers, automobiles, industrial control systems, aircraft, etc.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A plurality of flash memory cells coupled in series, wherein floating gates of adjacent memory cells have different cross-section thickness along a common vertical plane.

2. The memory cells of claim 1 wherein the adjacent floating gates are substantially identical to one another, and asymmetrical relative to a plane; and wherein the adjacent memory cells are flipped relative to one another along the plane.

3. The memory cells of claim 1 wherein the common vertical plane is a first common vertical plane, wherein one of the adjacent floating gates is thin and the other thick along the common vertical plane, wherein the adjacent floating gates are “L” shaped, and wherein the relationship of thin to thick reverses along another common vertical plane laterally offset from the first vertical plane.

4. The memory cells of claim 1 wherein a pair of adjacent floating gates comprises one thin floating gate and one thick floating gate, and wherein the relationship of thin to thick remains throughout an entirety of the pair of floating gates.

5. The memory cells of claim 1 wherein a pair of the adjacent memory cells includes one cell which stores a single bit of data and another cell which stores multiple bits of data.

6. A NAND cell unit comprising:
a plurality of flash memory cells coupled in series;
the flash memory cells comprising control gates over floating gates;
the flash memory cells comprising alternating first and second cell types; and
the second cell type having a greater thickness floating gate than the first cell type.

7. The NAND cell unit of claim 6 wherein the first cell type is a device that stores only single bits of data and wherein the second cell type is a device that stores multiple bits of data.

8. The NAND cell unit of claim 7 wherein the floating gates of the first cell type are the same in composition as the floating gates of the second cell type.

9. The NAND cell unit of claim 8 wherein the floating gates of the first and second cell types consist essentially of silicon.

10. The NAND cell unit of claim 7 wherein the floating gates of the first cell type are different in composition from the floating gates of the second cell type.

11. The NAND cell unit of claim 6 the first cell type is a single level cell (SLC) device, wherein the second cell type is a multilevel cell (MLC) device, wherein the floating gates of the first cell type comprise charge trapping material, and wherein the floating gates of the second cell type consist essentially of silicon.

12. The NAND cell unit of claim 6 wherein the first cell type comprises a different floating gate composition than the second cell type.

13. The NAND cell unit of claim 6 wherein the first cell type comprises a same floating gate composition as the second cell type.

14. A NAND cell unit comprising a plurality of flash memory cells; the flash memory cells comprising control gates over floating gates; at least one of the flash memory cells being a multilevel cell (MLC) and at least two of the flash memory cells being single level cells (SLCs), the MLC being interjacent a pair of the SLCs; the floating gates of the SLCs comprising charge trapping material and the floating gate of the MLC consisting essentially of silicon.

15. A NAND cell unit over a substrate, and comprising:
a plurality of flash memory cells; the flash memory cells comprising control gates over floating gates;
a first set of the flash memory cells having the control gates at first height over the substrate;
a second set of the flash memory cells having the control gates at a second height over the substrate; the second height being greater than the first height; the second set of flash memory cells having floating gates with portions at a common elevation with portions of the control gates of the first set of flash memory cells; and
individual gates of the first set alternating with individual gates of the second set.

16-19. (canceled)

20. A method of forming a NAND cell unit, comprising:
forming a first set of flash memory cells coupled in series; the first set of flash memory cells having first floating gates and first control gates; the first floating gates being formed to a first thickness; and
forming a second set of flash memory cells coupled in series with the first set of flash memory cells; the second set of flash memory cells having second floating gates and second control gates; the second floating gates being formed to a second thickness greater than the first thickness; the first control gates having portions at a common elevation as portions of the second floating gates.

21-26. (canceled)

27. A method of programming a NAND cell unit string gate, comprising:
providing the NAND cell unit to comprise a first string gate adjacent a second string gate; the first string gate comprising a first floating gate and a first control gate; the second string gate comprising a second floating gate and a second control gate; the first control gate being positioned for capacitive coupling to the second floating gate; and
utilizing capacitive coupling between the first control gate and the second floating to reduce the programming voltage during programming of the second string gate to a memory state.

28-30. (canceled)

31. A method of programming a NAND cell unit string gate, comprising:
providing the NAND cell unit to comprise a first string gate adjacent a second string gate; the first string gate comprising a first floating gate and a first control gate; the second string gate comprising a second floating gate and a second control gate; the first control gate being positioned for capacitive coupling to the second floating gate;
applying a first voltage to the first control gate;
applying a second voltage to the second control gate; and
increasing the first voltage while holding the second voltage substantially constant during programming of the second string gate to a memory state.

32-35. (canceled)

36. A method of programming a NAND cell unit string gate, comprising:
providing the NAND cell unit to comprise a first string gate adjacent a second string gate; the first and second string gates comprising control gates, floating gates and source/drain regions; the first control gate being positioned for capacitive coupling to the second floating gate;
providing a voltage differential between the control gate and source/drain regions of the second string gate; the voltage differential being less than a threshold differential for programming the second string gate to a memory state;
providing a pass voltage to the first string gate; and
while the voltage differential remains substantially constant, increasing the pass voltage to program the second string gate to the memory state.

37-40. (canceled)

41. A method of programming a NAND cell unit string gate, comprising:
providing the NAND cell unit to comprise a single level cell (SLC) type string gate adjacent a multilevel cell (MLC) type string gate;
providing a voltage to the MLC type string gate; the voltage being below a threshold for programming the MLC type string gate to a memory state;
providing a pass voltage to the SLC type string gate; and
while the voltage to the MLC remains substantially constant, increasing the pass voltage to program the MLC to the memory state.

42. The method of claim 41 wherein the memory state is the highest charged memory state of the MLC device.

43. The method of claim 41 wherein the SLC type string gate has a first floating gate and the MLC type string gate has a second floating gate; and wherein the second floating gate is thicker than the first floating gate.

44. The method of claim 41 wherein the first and second floating gates are the same composition as one another.

45. The method of claim 41 wherein the first and second floating gates differ in composition from one another.

46. The method of claim 41 wherein the first floating gate comprises a charge trapping material, and wherein the second floating gate consists essentially of silicon.
